(19) United States
(12) Patent Application Publication
(10) Pub. No.: US 2008/0017365 A1
(43) Pub. Date: Jan. 24, 2008

(54) HEAT SINK

(75) Inventors: HSIU-CHANG LAI, Tu-Cheng (TW); HUNG-YI WU, Tu-Cheng (TW); ZHEN-XING YE, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,641

(22) Filed: Sep. 1, 2006

(30) Foreign Application Priority Data
Jul. 21, 2006 (CN) 200610061753.9

(51) Int. Cl. H05K 7/20

(52) U.S. Cl. 165/185; 361/704; 257/722; 165/80.3

(57) ABSTRACT

A heat sink includes a heat-conductive base comprising a top surface; and a plurality of combined fins extending up from the top surface of the heat-conductive base, every two adjacent fins being spaced from each other with a passage formed therebetween, and the passage having an air inlet at one side of the heat sink, and an air outlet at an opposite side of the heat sink, wherein a top surface of each of the fins slopes down from the middle portion to the air inlet in a streamlined fashion, and from the middle portion toward the air outlet there is steeply sloping portion leading to a gently sloping portion terminating at a steeply sloping end surface of each of the fins. Resistance of the airflow is minimized, and speed of the heat dissipation is enhanced. Therefore, this aerodynamic design allows better airflow through the heat sink.

### CROSS-REFERENCES TO RELATED APPLICATION

Relevant subject matter is disclosed in co-pending U.S. patent application entitled “HEAT SINK” (US11302), assigned to the same assignee with this application.

### FIELD OF THE INVENTION

The present invention relates to heat sinks, and more particularly to a heat sink having high efficiency in dissipating heat.

### DESCRIPTION OF RELATED ART

Advances in microelectronics technology have resulted in electronic devices which process signals and data at unprecedented high speeds. During operation of many contemporary electronic devices, such as Central Processing Unit (CPU), large amounts of heat are produced. The heat must be removed instantly to prevent the system from becoming unstable or being damaged. Heat sinks are frequently used to dissipate heat from these electronic devices.

Referring to FIG. 1 and FIG. 2, a conventional heat sink 10 includes a base 12, and a plurality of combined fins 14 extending up from the base 12. The base 12 is a tablet shaped metal block with rectangular top and bottom surfaces. The heat sink 10 is attached to a top of an electronic device (not shown) for dissipating heat.

A fan (not shown) is set, to assist in dissipating heat, at a certain distance from the heat sink 10. Airflow 110 from the fan enters the heat sink 10 through an air inlet 13 of the heat sink 10, and exits from an air outlet 15 of the heat sink 10. A side of each of the fins 14 at the air inlet 13 is approximately vertical to the airflow. Additionally, the side of each of the fins 14 has a certain width. Thus, resistance of the airflow 110 increases when the airflow 110 passes across the sides of the fins 14 of the heat sink 10, and heat dissipation efficiency of the heat sink 10 is low.

What is desired, therefore, is a heat sink which provides high efficiency of heat dissipation.

### SUMMARY OF THE INVENTION

In one preferred embodiment, a heat sink includes a heat-conductive base comprising a top surface; and a plurality of combined fins extending up from the top surface of the heat-conductive base, every two adjacent fins being spaced from each other with a passage formed therebetween, and the passage having an air inlet at one side of the heat sink, and an air outlet at an opposite side of the heat sink, wherein a top surface of each of the fins slopes down from the middle portion to the air inlet in a streamlined fashion, and from the middle portion toward the air outlet there is steeply sloping portion leading to a gently sloping portion terminating at a steeply sloping end surface of each of the fins.

Other advantages and novel features will become more apparent from the following detailed description of preferred embodiments when taken in conjunction with the accompanying drawings, in which:

### BRIEF DESCRIPTION OF THE DRAWINGS

FIG. 1 is an isometric view of a conventional heat sink;

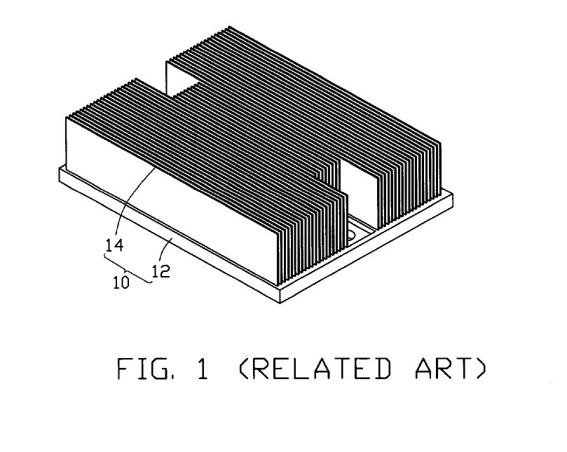

FIG. 2 is a front view of FIG. 1;

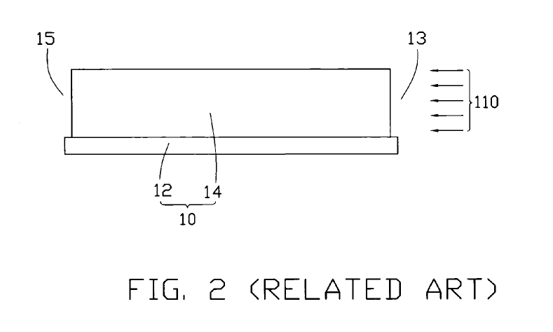

FIG. 3 is an isometric view of a heat sink, in accordance with a preferred embodiment of the present invention; and

FIG. 4 is a front view of FIG. 3.

### DETAILED DESCRIPTION OF THE INVENTION

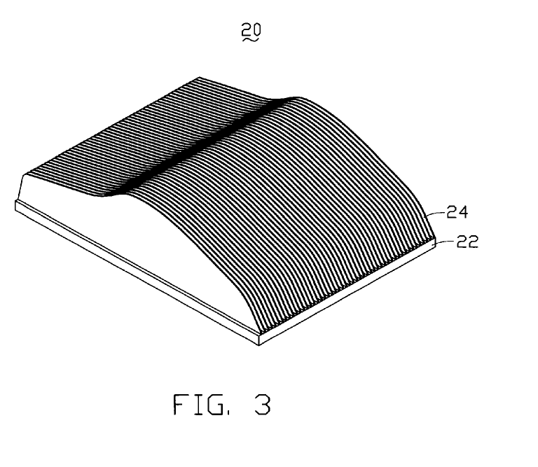

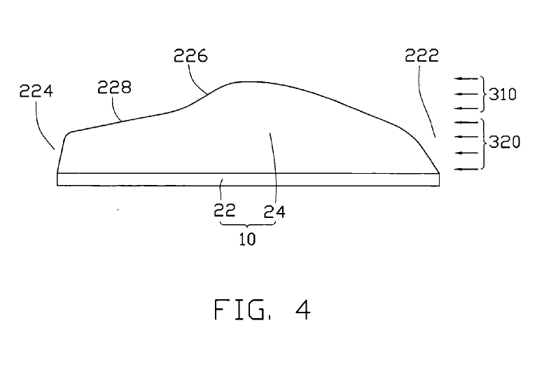

As shown in FIG. 3 and FIG. 4, in a preferred embodiment of the present invention, a heat sink 20 includes a heat-conductive base 22, and a plurality of combined fins 24 extending up from the heat-conductive base 22. Every two adjacent fins 24 are spaced from each other with a passage formed therebetween. The passage has an air inlet 222 at one side of the heat sink 20 and an air outlet 224 at an opposite side of the heat sink 20.

A fan (not shown) is set, to assist in dissipating heat, at a certain distance from the heat sink 20. A profile of each of the fins 24 is generally in a streamlined shape, and forms a raised middle portion thereof such as a convex curving portion. A top surface of each of the fins 24 slopes down from the middle portion to the air inlet 222 in a streamlined fashion until the top surface of each of the fins 24 reaches a steeply sloping end surface of each of the fins 24 generally vertically aligned with an end of the heat-conductive base 22, and from the middle portion toward the air outlet 224 there is steeply sloping portion 226 leading to a gently sloping portion 228 terminating at another steeply sloping end surface of each of the fins 24 generally vertically aligned with another end of the heat-conductive base 22. In another words, each of the fins 24 defines a concave curving portion adjoining one side of the convex curving portion adjacent to the outlet 224, and another convex curving portion away from the outlet 224. A linear portion, and a slant portion, in that order extend from the concave curving portion toward the outlet 224. Another linear portion is connected between the convex curving portion and the another convex curving portion. A slant portion extending from said another convex curving portion to the inlet 222.

The heat sink 20 is configured to attach to a heat producing electronic device (not shown), such as a Central Processing Unit (CPU), for heat dissipation. The electronic device is located under, and attached to a bottom surface of the heat-conductive base 22.

Because the top surface of each of the fins 24 slopes down in a streamlined fashion from the middle portion toward the air inlet 222 resistance of the airflow is minimized. Therefore, this aerodynamic design allows better airflow through the heat sink 20.

Additionally, the airflow from the fan includes a first airflow 310 passing through an upside of each of the fins 24, and a second airflow 320 passing through remaining parts of each of the fins 24. Because the top surface of each of the fins 24 slopes down steeply at first and then gently from the middle portion toward the air outlet 224, the first airflow 310 carries away communicated at the upside of the fins 24 after exiting past the steep portion 226, and the second airflow 320 carries away communicated at the lower side of the fins 24 exiting from the air outlet 224. That is to say, interference between the first airflow 310 and the second airflow 320 is reduced during heat dissipation. Thus, a speed of the heat dissipation is enhanced, and the heat dissipation efficiency of the heat sink 20 is improved.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. A heat sink comprising:
a heat-conductive base comprising a top surface; and
a plurality of combined fins extending up from the top surface of the heat-conductive base, every two adjacent fins being spaced from each other with a passage formed therebetween, and the passage having an air inlet at one side of the heat sink, and an air outlet at an opposite side of the heat sink, wherein a top surface of each of the fins slopes down from the middle portion to the air inlet in a streamlined fashion, and from the middle portion toward the air outlet there is steeply sloping portion leading to a gently sloping portion terminating at a steeply sloping end surface of each of the fins.

2. The heat sink as claimed in claim 1, wherein the top surface of each of the fins slopes down from the middle portion to the air inlet until the top surface of each of the fins reaches another steeply sloping end surface of each of the fins generally vertically aligned with an end of the heat-conductive base.

3. The heat sink as claimed in claim 1, wherein the top surface of each of the fins the steeply sloping end surface of each of the fins is generally vertically aligned with an end of the heat-conductive base.

4. A heat sink comprising:
a base configured for attaching to a heat-generating component; and
a plurality of parallel fins extending from the base, a passage being formed between any two adjacent fins and comprising an inlet at one side of the fins and an outlet at an opposite side of the fins, a top surface of each of the fins comprising a convex curving portion at a middle thereof, a concave curving portion adjoining one side of the convex curving portion adjacent to the outlet, and another convex curving portion away from the outlet.

5. The heat sink as claimed in claim 4, wherein the top surface further comprises a linear portion connected between said convex curving portion and said another convex curving portion.

6. The heat sink as claimed in claim 5, wherein the top surface further comprises a slant portion extending from said another convex curving portion to the inlet.

7. The heat sink as claimed in claim 4, wherein the top surface further comprises a linear portion extending from the concave curving portion toward the outlet.

8. The heat sink as claimed in claim 7, wherein the top surface further comprises a slant portion extending from the linear portion to the outlet.
